(19) United States
(12) Patent Application Publication
(10) Pub. No.: US 2014/0099491 A1
(43) Pub. Date: Apr. 10, 2014

(54) Plasma Etch Resistant Films, Articles Bearing Plasma Etch Resistant Films and Related Methods

(71) Applicants: Mohammed Ameen, Souderton, PA (US); Sang-Ho Lee, North Wales, PA (US); Thomas Mercer, Annapolis, MD (US); Vasil Vorsa, Coopersburg, PA (US)

(72) Inventors: Mohammed Ameen, Souderton, PA (US); Sang-Ho Lee, North Wales, PA (US); Thomas Mercer, Annapolis, MD (US); Vasil Vorsa, Coopersburg, PA (US)

(21) Appl. No.: 13/647,949

(22) Filed: Oct. 9, 2012

(51) Int. Cl. C01F 17/00; C23C 16/40; H01L 21/02

(52) U.S. Cl. CPC C01F 17/0043; H01L 21/02192; C23C 16/405
USPC 428/220; 423/263; 427/248.1; 427/576; 427/535; 216/67

(57) ABSTRACT

The invention includes a plasma etch-resistant film for a substrate comprising a yttria material wherein at least a portion of the yttria material is in a crystal phase having a crystal lattice structure, wherein at least 50% of the yttria material is in a form of a monoclinic crystal system. The film may be treated by exposure to a fluorine gas plasma. Also included are plasma etch-resistant articles that include a substrate and a film, wherein the film comprises an yttria material and at least a portion of the yttria material is present in the film in a crystal phase having a crystal lattice structure and at least 50% of the yttria material is in a form of a monoclinic crystal system. Several methods are contemplated within the scope of the invention.

### CROSS REFERENCE TO RELATED APPLICATION

This application claims the benefit under 35 U.S.C. §119(e) to U.S. Provisional Patent Application No. 61/544,022, filed Oct. 6, 2011, the entire disclosure of which is incorporated herein by reference.

### BACKGROUND OF THE INVENTION

Resistance to plasmas is a desirable property for components used in processing chambers where corrosive environments are present. Process chambers and component apparatus present within or used in conjunction with processing chambers which are used in the fabrication of electronic devices and MEMS are frequently constructed from various substrates such as sapphire, silica, fused silica, quartz, fused quartz, alumina, silicon, aluminum, anodized aluminum, zirconium oxide, an aluminum alloy, and sapphire, as these materials are known to have a level of plasma resistance and/or are commonly used in semicon apparatuses for other reasons.

These materials, however, may be easily eroded during routine processing conditions whether chemically, physically, and/or thermally. Typically, the most severe environments are presented to the substrates during plasma etch processes, whether as part of etch processing or chamber cleaning. To ameliorate the erosion or degradation of the substrates, attempts have been made to protect and preserve them by application of a coating. The aim of such coating is to act to reduce exposure to various plasmas (NF₃, Cl₂, CHF₃, CH₂F₂, SF₆ and HBr) and thereby prevent or reduce weight loss and/or to reduce particulation during dry etching processes where particles may be dislodged from the chamber walls and various components inside the processing chamber.

Conventional films and methods have been used in an attempt to develop a suitable coating. For example, films that contain various ceramic materials such as alumina, aluminum nitride, and zirconia that are known to be chemically stable in plasma etching conditions have been prepared. Although these films often exhibit improved plasma resistance in the form of reduced weight loss, they still frequently generate unwanted particulates. Particulates liberated in the processing chamber result in damaged or flawed wafers, which must then be discarded, increasing the cost of production, and reducing production line efficiency.

As an example, alumina-coated silica or alumina-coated quartz are known to exhibit a reduced etch rate, as compared to bare silica or quartz. However, in a fluoride-containing etch environment, one finds that alumina from the film is fluorinated, forming aluminum fluoride, a highly stable and non-volatile compound that builds on chamber walls. Subsequently, the aluminum fluoride particulates shed off the chamber walls and contaminate the wafers.

Several prior attempts have been made to reduce particulation by coating quartz substrates with yttria. These attempts have mostly been with very thick (typically >50 micron) thermal-spray yttria. Nonetheless, thermal-prayed yttria films are porous and still generate undesired levels of particulation.

Accordingly, there remains a need in the art for a film that can be applied to substrates that is resistant to degradation upon exposure to plasma and exhibits reduced particulation.

### BRIEF SUMMARY OF THE INVENTION

The invention includes a plasma etch-resistant film for a substrate comprising a yttria material wherein at least a portion of the yttria material is in a crystal phase having a crystal lattice structure, wherein at least 50% of the yttria material is in a form of a monoclinic crystal system.

Also included are plasma etch-resistant articles that include a substrate and a film, wherein the film comprises an yttria material and at least a portion of the yttria material is present in the film in a crystal phase having a crystal lattice structure and at least 50% of the yttria material is in a form of a monoclinic crystal system.

Several methods are contemplated within the scope of the invention. A method of manufacturing an article comprising depositing an yttria material on a substrate to form a film, wherein the film comprises the yttria material and at least a portion of the yttria material present in the film is in a crystal phase having a crystal lattice structure, wherein at least 50% of the yttria material present in the film is in a form of a monoclinic crystal system. Also included is a method of increasing the plasma etch resistance of a substrate comprising depositing a yttria material on the substrate to form a film on the surface(s) of the substrate, wherein the film comprises the yttria material and at least a portion of the yttria material present in the film is in a crystal phase having a crystal lattice structure, wherein at least 50% of the yttria material present in the film is in a form of a monoclinic crystal system and a method of manufacturing a plasma resistant film having increased fracture toughness on a substrate comprising depositing a yttria material on the substrate to form a film on the surface(s) of the substrate, wherein the film comprises the yttria material and at least a portion of the yttria material present in the film is in a crystal phase having a crystal lattice structure, wherein at least 50% of the yttria material present in the film is in a form of a monoclinic crystal system.

### BRIEF DESCRIPTION OF THE SEVERAL VIEWS OF THE DRAWING(S)

The foregoing summary, as well as the following detailed description of embodiments of the invention, may be better understood when read in conjunction with the appended drawings. It should be understood, however, that the invention is not limited to the precise arrangements and instrumentalities shown in the drawings. In the drawings:

FIG. 1 is a cross sectional representation of a polycrystalline corrosion resistant yttria film on a substrate;

FIG. 2, including FIGS. 2a and 2b, shows x-ray diffraction (XRD) measurements of two films prepared in accordance with the invention;

FIG. 3 is an XRD pattern of polycrystalline Y₂O₃ film on fused quartz containing both monoclinic and cubic phases.

FIG. 4, includes FIGS. 4a and 4b. 4a shows cross-sectional SEM images of fused quartz coated with cubic/monoclinic mixed-phase Y₂O₃ prior to direct NF₃ plasma exposure; 4b is cross-sectional SEM image of same Y₂O₃ coated fused quartz sample in FIG. 4a following 4 hours of direct NF₃ etching.

FIG. 5 shows an optical image of fused quartz with coated and uncoated areas exposed to 80 hours of remote NF₃ plasma. The uncoated area was etched by the NF₃ remote plasma resulting in approximately 1 mm of quartz removal correlating to an etch rate of ˜210 nm per minute. In contrast, the mixed-phase Y₂O₃ coated areas show no signs of etching, thus exhibiting protective coating capability.

### DETAILED DESCRIPTION OF THE INVENTION

The invention described herein includes plasma etch resistant films for substrates, articles that include the films applied to substrates, methods of manufacturing the articles, and/or preparing the films, and methods of increasing the plasma etch resistance of a substrates. Also included are films prepared by the invention which exhibit increased fracture toughness.

It is well known that coating a substrate with a film can increase the substrate's resistance to etching by plasmas. In the prior art, this is achieved (i) if the film is made of a sacrificial material, i.e., one that is gradually removed from the substrate with each successive plasma exposure, preventing for a limited time degradation of the substrate itself, or (i) if the film is made of a material that is not necessarily practical for use as a structural element in, for example, a semicon processing apparatus, but which has a greater resistance to plasmas than the substrate (which is suitable for use as a structural element). In each case, the continued exposure to the harsh environments of the plasmas eventually and inevitably degrades the film and/or the substrate and the component part of the apparatus must be replaced. In some cases, particulation develops as a side effect of the degradation of the film or substrate, potentially resulting in the wasting of extremely expensive semicon wafers or equipment.

To reduce the costs associated with part replacement, particulation, and the associated equipment downtime, persons of skill in the art have been in constant pursuit of materials that are less easily degraded or that degrade at a slower rate for use as either substrate or film. The inventors have found that that a substrate's resistance to degradation upon exposure to gas plasma can be improved by forming a film having a structure that contains mixed crystal systems, but wherein at least 50% of the crystals are in the form of a monoclinic crystal system. In some embodiments, if the film prepared as described herein exhibits one or more desirable properties, including reduced rate of plasma etching (under exposure to corrosive chemicals or plasmas), reduced particulation during use in a semiconductor process, and other degradation under exposure to gas plasmas, such as those containing fluorine.

The invention includes a plasma etch-resistant film for use on various substrates. By “plasma etch resistant”, it is meant that the film of the invention, upon exposure to corrosive chemicals, such as gas plasmas (and particularly fluorine plasmas) is less degraded than is a conventional yttria film. Degradation or lack of degradation of the films may be evaluated using any means commonly accepted in the art including visual means such as optical or scanning electron microscopy, wherein areas of cracks, fissures, and undercutting are assessed or by evaluation of the adhesion of the film to the substrate, where greater adhesion corresponds to less degradation.

The film is prepared by depositing an yttria material on a substrate. The film is formed by deposition or application of yttria material onto a substrate. The yttria material may be any yttria-containing or yttria-derived material that exhibits a level of plasma resistance and/or reduced particulation when exposed to a plasma-containing environment, particularly, for example an environment containing fluorine-based plasma. Exemplary yttria materials include without limitation yttria, yttrium aluminum garnet, yttria containing one or more dopant or other additives, or combinations of these materials.

The yttria material is deposited on the substrate so that the film formed contains the yttria material in crystal phase with a crystal lattice structure, and at least 50% of the crystal phase yttria material is in a form that is described by a monoclinic crystal system. Thus, the film is deposited on the substrate such that at least a portion of the yttria material is present in the film in a monoclinic phase. Yttria may exist in a polycrystalline form and such crystals are commonly understood to have a structure represented by a cubic system (cubic). As in known in the art, yttria is commonly found as amorphous (non-crystalline) or in the cubic crystal structure, although in some circumstances, it may be present on other crystal system forms, such as for example, in a cubic, a hexagonal, a tetragonal, an orthorhombic, and/or a triclinic crystal system.

In the practice of the invention, in some embodiments, however, it may be preferred that at least 60% of the yttria material, at least 65% of the yttria material, at least 70% of the yttria material, at least 75% of the yttria material, at least 80% of the yttria material, at least 85% of the yttria material, at least 90% of the yttria material, at least 95% of the yttria material, at least 98% of the yttria material or at least 99% of the yttria material is in a form of a monoclinic crystal system.

The remainder of the yttria material present in the film may exist in any crystal structure. For example, if 55% of the yttria material present in the film exists in a form of a monoclinic crystal system, the remaining 45% may exist as 100% of any other form, or a mixture of other forms. For example, the remaining portion of yttria material may be in alternative forms or phases or mixtures of forms or phases, including, for example, amorphous, cubic, hexagonal, tetragonal, orthorhombic, and/or a triclinic crystal systems. This remaining portion may be hereinafter referred to as “non-monoclinic.”

In the film, the yttria material that is in monoclinic form (as well as the other phases or forms present) can either contains random crystallite orientation or preferred crystallite orientation. For example, the monoclinic phase may contain completely random crystallite orientations or an orientation in the (40 2̅) orientation, which may in some circumstances, be preferred. Similarly, the non-monoclinic portion of the film may also have a random or preferred orientation. For example, the non-monoclinic phase may contain completely random crystallite orientation or a (222) orientation.

The film may have any average crystallite size or grain size and the grain size may vary as a function of the thickness of the film. However, in some embodiments of the invention or circumstances of practice of the invention, it may be preferred that the average crystal size of the crystallites that are present in the film have about 100 Å to about 1000 Å or about 200 Å to about 500 Å, as measured by X-ray diffraction. The monoclinic portions and the non-monoclinic portion(s) may have the same or may have different average crystal sizes.

The film may be any thickness, and such thickness will vary depending on the specific end use or end application to which the substrate/film article is applied. In most circumstances, it may be desirable that the film has a thickness of about 0.1 to about 30 microns, about 0.5 to about 25 microns, about 1 micron to about 5 microns, about 10 microns to about 20 microns, and/or about 15 microns to about 25 microns.

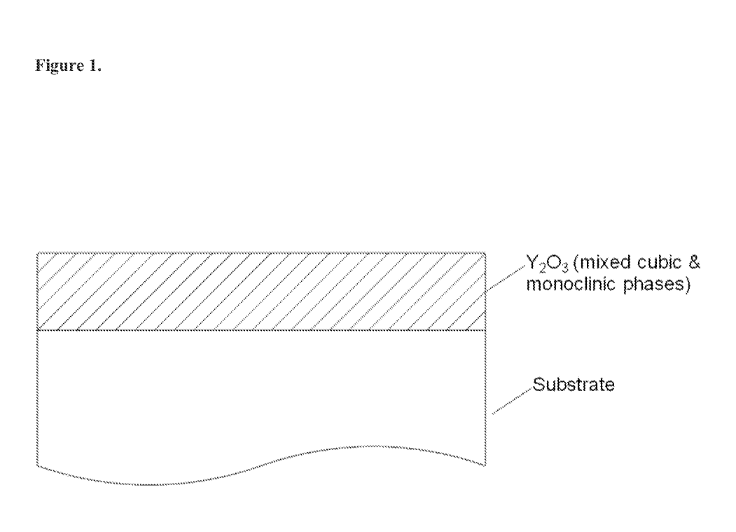

A schematic, cross-sectional representation of a polycrystalline corrosion-resistant film on a substrate is shown in FIG. 1.

The film may be applied/deposited continuously or discontinuously along the surface of the substrate. By discontinuous, it is meant that the film may be present on only a portion or portions of the substrate (e.g., in patches), and the remaining portions are bare substrate or are coated with another material(s). Continuity/discontinuity of the film will necessarily vary depending on the contemplated end application for the film-coated substrate.

The films of the invention are deposited on one or more substrates. The substrates may be any known in the art, although it may be preferred that the selected substrate is one commonly used in semiconductor processing and which may have a level of inherent resistance to plasma etch, high temperatures, corrosive chemicals, and/or high pressures. For example, in some circumstances, it may be preferable that the substrate is a material that, independent of the film, has one or more high performance properties, such as resistance to corrosive chemicals, resistance to high temperatures and/or pressures, resistance to gas plasmas, mechanical strength, hardness, etc. Exemplary substrates may include polymers, metals, silica, fused silica, fused quartz, quartz, alumina, sapphire, silicon, silicon nitride, silicon carbide, aluminum, alumina, anodized aluminum, and or zirconium oxide. In some circumstances, silicon, alumina and/or quartz materials may be preferred.

In some embodiments, the substrate may be in the format of a semiconductor processing apparatus component or a portion of a semiconductor processing apparatus component. Such components include any known or developed in the art. Exemplary components may include, without limitation, a chamber wall, a chamber floor, a screw, a wafer boat or other tool or device used to position the wafer(s), a fastener, a window, a dispersion disc, a shower head, an electrostatic chuck, a fastener, a cooling plate, a CEL plate, a focus ring, an inner ring, an outer ring, a capture ring, an insert ring, a gas transfer tube, and a heater block.

The films of the invention may be deposited or applied to the substrates by any means in the art, including but not limited to, physical vapor deposition (PVD) processes including, but not limited to: evaporation deposition (electron beam vapor deposition), sputter deposition, arc vapor deposition, and ion plating electron beam vapor deposition, as well as chemical vapor deposition processes including, but not limited to: atmospheric pressure CVD (APCVD), low-pressure CVD (LPCVD), aerosol assisted CVD (AACVD), plasma enhanced CVD (PECVD), atomic layer CVD (ALCVD or ALD), metallorganic CVD (MOCVD), and initiated CVD (iCVD). The specific process parameters under which the film is applied/deposited may vary depending on the method of application or deposition used, although such minor variations within the ordinary skill of one in the art familiar with such processes. In one embodiment, it may be preferred that the film is formed by depositing the yttria material on a substrate that has a temperature of about 21° C. to about 500° C.

As a non-limiting, general example of the practice of the invention, a deposition process using a quartz substrate and an electron beam process may include: pre-cleaning of the bare substrate using a solvent, such as, for example, an organic solvent like isopropyl alcohol and pre-heating of the electron beam chamber to a temperature in range of about 25° C. to about 600° C.

Typically the time necessary to achieve preheating of the substrate is about 0.5 to about 4 hours, depending on the substrate mass; optional in-situ pre-cleaning of substrate using an ion beam. If this pre-cleaning step is undertaken, the gases used may be argon (most typical), oxygen, oxygen/argon blend, or other noble gases such as xenon. An exemplary process may use yttrium metal ingots having a high purity, such as 90% or greater, preferable 98% or greater purity. The yttrium metal ingots are pre-melted in a single step or in multiple steps prior to deposition and may be deposited onto the substrate at a rate of about 0.1 to about 10 micrometers per hour. During deposition, oxygen gas is introduced into the chamber as an ambient background gas in a partial pressure range of about 1×10⁻⁵ to 1×10⁻³ torr.

In some embodiments, ion beam assisted deposition (IBAD) may be used to carryout the deposition, which utilizes a separate vaporization source and bombardment source. For example, in such process, yttrium metal is thermally evaporated via electron beam evaporation and oxygen is introduced as the bombardment source. In some embodiments, the oxygen can be mixed with other gases such as argon, neon, or xenon, to increase densification. In a further embodiment, films can be grown by evaporating yttrium and still introducing oxygen as an ambient background gas while using an ion gun to bombard the film with a secondary gas such as argon or xenon to increase film density.

After deposition, film-coated substrate is cooled back to room temperature in a controlled manner, for example at a rate of about 1° C. to about 200° C. per hour.

Regardless of the processes selected, it may be desirable that the yttria material is grown on the substrate to form a film when the substrate is about room temperature (21 ° C.) to about 500° C., about 100° C. to about 500° C., and/or about 400° C. to about 500° C.

In any of the process described herein the yttria material may be deposited or applied directly on to the surface of the substrate (that is, the film is formed directly against the surface of the substrate). Alternatively, the substrate may be coated with other materials (forming one or more intervening layers of films) prior to the deposition of the yttria material. In addition or alternatively, the film of the invention, once formed, may be coated with additional layer(s), for example an extra sacrificial layer of alumina, to further enhance overall plasma resistance. The invention also includes methods of manufacturing a plasma resistant film having fracture toughness on a substrate and the resultant films.

In some embodiments of the invention, it may be desirable to subject the film to a post-deposition process or treatment to enhance, refine or further develop one or more desirable properties of the film, the substrate and/or the film-substrate combination. Such process may include any known or too be developed in the art. In an embodiment, one may wish to subject the film-bearing substrate to a fluorine plasma treatment. Such treatment may be carried out using any means in the art, for example without limitation, by treatment using a remote plasma sources or a reactive ion etch treatment. In some embodiments, one may expose the film-bearing substrate to a fluorine plasma treatment for about 1 hour, about 2 hours, about three hour, about 4 hours, about 5 hours, about 6 hours or about 10 or more hours.

Films that are exposed to fluorine gas plasmas as described may exhibit increased resistance to fracture under thermal cycling conditions as compared to conventional films and/or films of the invention that are not exposed to the plasma treatment

### EXAMPLE I

Two sets of yttrium oxide films were grown on fused quartz coupons (dimensions: 1 inch×1 inch; ⅛ inch thick) through reactive deposition using electron beam evaporation. Each coupon was installed in the electron beam film chamber and the chamber was placed under vacuum overnight. The film chamber vacuum level was maintained at 5×10⁻⁶ torr (or lower) and preheated for at least 1 hour to ensure temperature equilibrium was reached.

High purity (>99.9%) yttrium metal target was evaporated by electron beam and oxygen was bled in to the chamber to maintain a chamber process pressure between 5.5×10⁻⁵ torr to 1×10⁻⁴ torr. Each coupon was coated for 4 hours to reach target thickness of about 4 microns. During the film process, temperature of the substrate was maintained between about 250° C. to about 350° C.

One set of films was grown to produce an yttria film containing approximately 50% cubic phase and 50% monoclinic phase. The second set was grown to produce films containing predominantly monoclinic phase yttria (50% or greater).

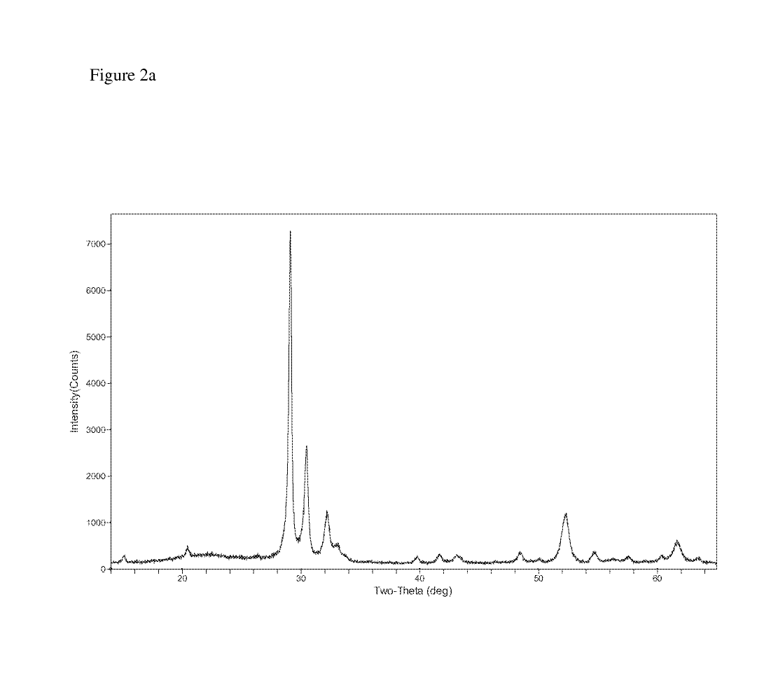

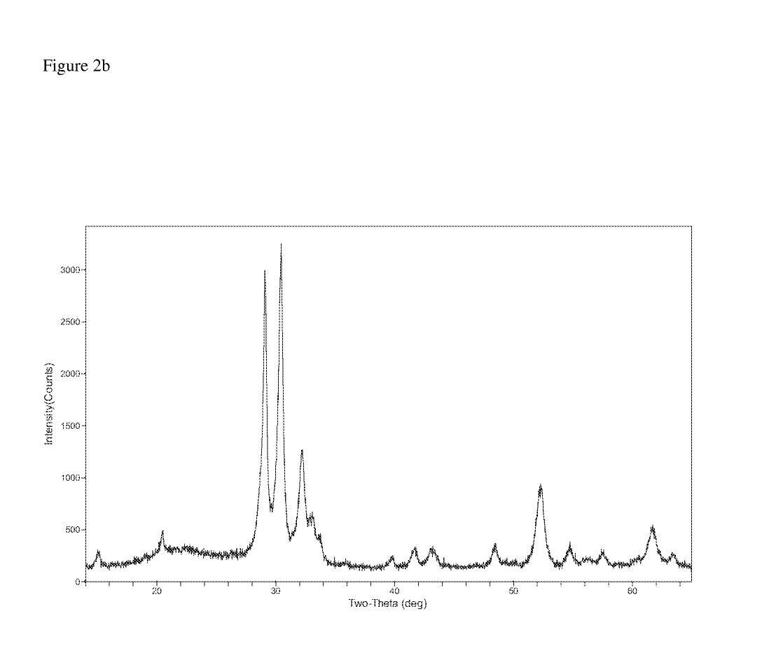

FIG. 2, including FIGS. 2a and 2b, shows x-ray diffraction (XRD) measurements of the two films. FIG. 2a shows a typical XRD pattern containing approximately 50% monoclinic and 50% cubic phases. Line marker overlays are provided to identify peaks belonging to monoclinic and cubic phases. Peaks prefaced with (1) belong to cubic phase and peaks prefaced with (2) belong to the monoclinic phase. Note, the reflected intensity from the cubic phase is roughly 4× the reflected intensity from the monoclinic phase for the same amount of yttria. Consequently, the ratio of cubic to monoclinic integrated XRD intensity for equal amounts of cubic and monoclinic phase yttria will be 4 to 1. FIG. 2b shows X-ray diffraction spectra of electron beam deposited Y₂O₃ film on fused quartz showing a ratio of about 18 to about 82 percent of cubic to monoclinic Y₂O₃ phases.

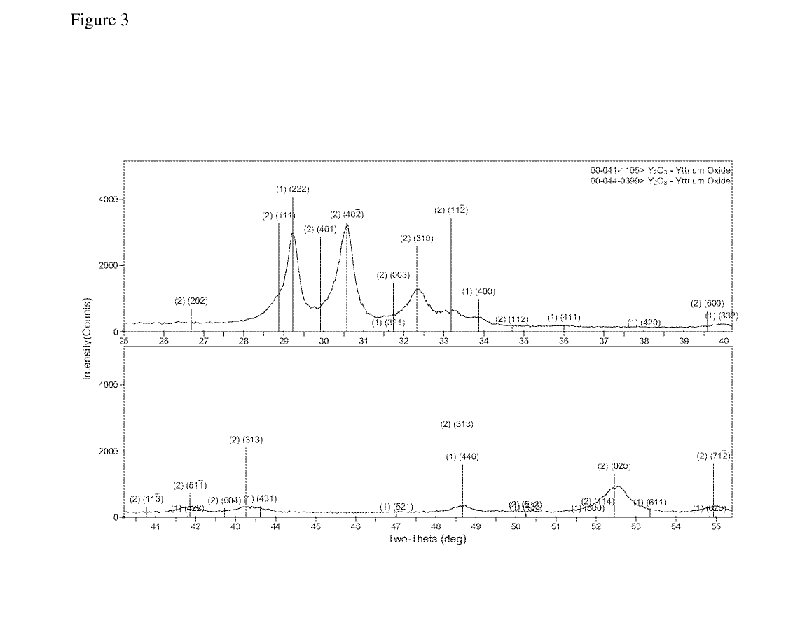

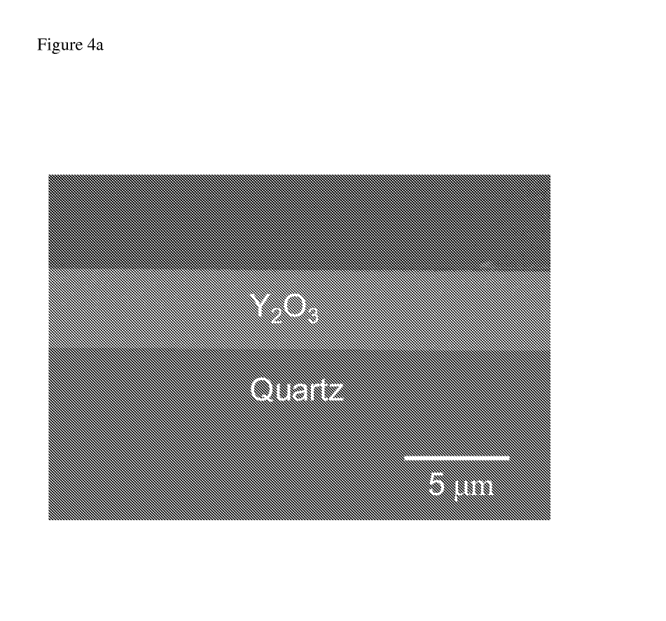

FIG. 3 shows a typical XRD pattern containing approximately 50% monoclinic and 50% cubic phases. Line marker overlays are provided to identify peaks belonging to monoclinic and cubic phases. Peaks prefaced with (1) belong to cubic phase and peaks prefaced with (2) belong to the monoclinic phase.

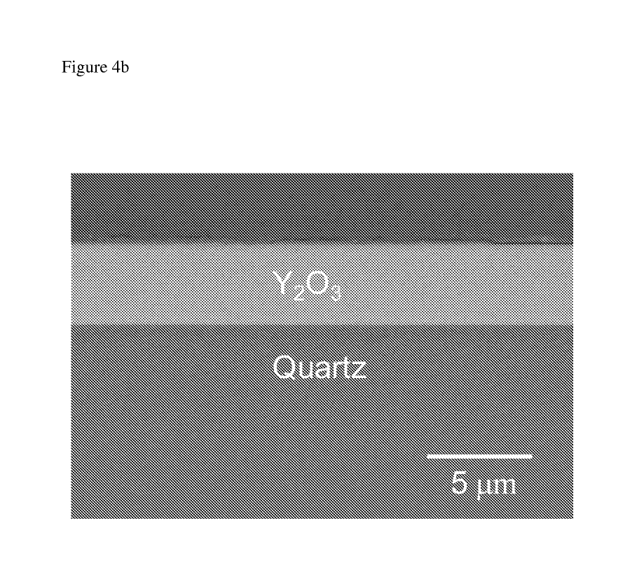

FIG. 4 shows cross-sectional SEM images of mixed cubic and monoclinic phase yttria film on fused quartz prior to (5A) and subsequent to (5B) 4 hours of direct NF₃ plasma etch. Rietveld XRD analysis of the as coated film indicates that it consists of 72% monoclinic phase yttria and 28% cubic phase yttria. FIG. 4B essentially shows that there is no change in thickness of the yttria film following 4 hours for NF₃ plasma etch. Uncoated fused quartz, on the other hand, would exhibit a loss of ˜100 microns of surface material in 4 hours under the same plasma conditions.

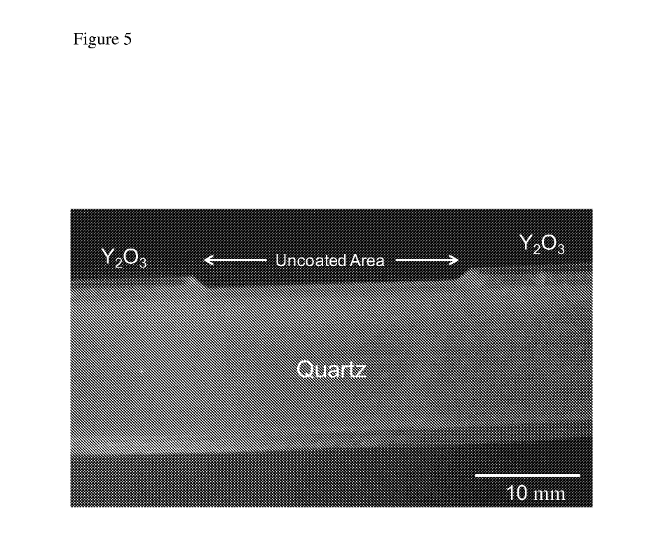

FIG. 5 shows an optical image of a partially coated fused quartz substrate exposed to 80 hours of remote NF₃ plasma. The central area of the fused quartz piece was masked and therefore is uncoated. Both the left and right side of the sample is coated with mixed phase yttria. Rietveld analysis indicates that the film consists of approximately 65% monoclinic phase yttria and 35% cubic phase yttria. Examination the etched area shows that the fused quartz was etched away to a depth of about 1 millimeter corresponding to an etch rate of about 0.2 microns per minute. The yttria-coated areas, on the other hand, protected the underlying fused quartz from being etched.

### EXAMPLE 2

Three sets of yttria films on quartz coupons were prepared using standard deposition conditions. One set of films was processed further by exposing the films to a direct NF₃ plasma in a capacitively coupled parallel plate reactive ion etch (RIE) reactor. Another set was processed by exposing the films to a remote NF₃ plasma source. The third set of films had no further processing after coating. The films were then thermally cycled on a hot stage equipped microscope and the point of fracture formation was recorded. Yttrium oxide films for thermal cycle experiments were grown on fused quartz coupons (dimensions: 1 inch×1 inch; ⅛ inch thick) by electron beam evaporation. Each coupon was installed in the electron beam film chamber and the chamber was placed under vacuum overnight. The film chamber vacuum level was maintained at 5×10⁻⁶ torr(or lower) and preheated for at least 1 hour to ensure temperature equilibrium was reached. High purity (>99.9%) yttrium metal target was evaporated by electron beam and oxygen was bled in to the chamber to maintain a chamber process pressure between 5.5×10⁻⁵ torr to 1×10⁻⁴ torr. During the film process, temperature of the substrate was maintained between about 250° C. to about 350° C.” Two coating runs were made with deposition times of 220 minutes and 160 minutes in order to generate two coupons with thicknesses of 2.8 and 3.9 μm.

Two types of plasma treatment for fluorination of the yttria films were used. All plasma treatments were carried out on a Trion Phantom II RIE system equipped with a remote plasma source (MKS ASTRONex AX7685 RPS). Direct etch experiments utilized the RIE process. Reactive ion etch treatment conditions were as follows:

| Parameter | |
|---|---|
| NF₃ Flow | 65 sccm |
| O₂ Flow | 3 sccm |
| Pressure | 500 mTorr |
| Power | 350 W |
| Etch time | 4 hours |

Remote plasma conditions were as follows:

| Parameter | |
|---|---|
| NF₃ Flow | 500 wsccm |
| Air Flow | 100 sccm |
| Pressure | 2 Torr |
| Etch Time: | 4 hours |

Thermal cycle experiments were carried out on an Olympus microscope (model: BX60F5) equipped with a Linkam Hot Stage (model: LTS420). The coupons were placed film side down onto the hot stage and the films were monitored through the quartz substrate for cracking with a 50× objective focused onto the film surface. The hot stage was programmed to ramp from 40° C. to 200° C. at a rate of 10° C. per minute for 10 or more complete cycles.

Table I summarizes the results of the effect of fluorination on cracking. All films that did not receive any fluorination treatment exhibited cracking within the first several thermal cycles. Films that received fluorination treatment, regardless of remote or direct etch, exhibited no cracking after 10 or more cycles.

TABLE I
Thermal cycle data. 10 cycles from 40° C. to 200° C. at 10° C./min.

| Coupon | Plasma Treatment | Film Thickness | Cycle of 1^{st} Crack |
|---|---|---|---|
| 1 | None | 3.9 | 1 |
| 2 | None | 3.9 | 2 |
| 3 | None | 2.8 | 2 |
| 4 | None | 2.8 | 3 |
| 5 | RIE NF3 | 3.9 | No Cracks |
| 6 | RIE NF3 | 2.8 | No Cracks |
| 7* | Remote NF3 | 2.8 | No Cracks |
| 8* | Remote NF3 | 2.8 | No Cracks |

*These samples were cycled up to 30 times without cracking

As is demonstrated by the data shown in the table, film fracture toughness is increased during thermal cycling with fluorinating of yttrium oxide films with a fluorine-based plasma by application of the invention. No cracks appeared in the coupons coated in accordance with the invention, while cracks appeared almost immediately (e.g., in the 1^{st}, 2^{nd} or 3^{rd} cycles) of the control coupons.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A plasma etch-resistant film for a substrate comprising a yttria material wherein at
least a portion of the yttria material is in a crystal phase having a crystal lattice structure, wherein at least 50% of the yttria material is in a form of a monoclinic crystal system.

2. The film of claim 1, wherein at least 60% of the yttria material is in a form of a monoclinic crystal system.

3. The film of claim 1, wherein at least 65% of the yttria material is in a form of a monoclinic crystal system.

4. The film of claim 1, wherein at least 70% of the yttria material is in a form of a monoclinic crystal system.

5. The film of claim 1, wherein at least 75% of the yttria material is in a form of a monoclinic crystal system.

6. The film of claim 1, wherein at least 80% of the yttria material is in a form of a monoclinic crystal system.

7. The film of claim 1, wherein at least 85% of the yttria material is in a form of a monoclinic crystal system.

8. The film of claim 1, wherein at least 90% of the yttria material is in a form of a monoclinic crystal system.

9. The film of claim 1, wherein a portion of the yttria material that is not in a form of a monoclinic crystal system, is a form chosen from one or more of an isomeric crystal system, a hexagonal crystal system, a tetragonal crystal system, an orthorhombic crystal system, and a triclinic crystal system.

10. The film claim 1, wherein the substrate is chosen from silica, fused silica, quartz, fused quartz, alumina, and sapphire.

11. The film of claim 1, wherein the substrate is chosen from silicon, silicon carbide, silicon nitride, aluminum, anodized aluminum, zirconium oxide, and aluminum alloy.

12. The film of claim 1, wherein the film has a thickness of about 0.1 microns to about 30 microns.

13. The film of claim 1, wherein the film has a thickness of about 0.5 micron to about 25 microns.

14. The film of claim 1, wherein the film has a thickness of about 1 micron to about 5 microns.

15. The film of claim 1, wherein the yttria material is yttria.

16. The film of claim 1, wherein the yttria material is an yttria-derived composite.

17. The film of claim 1, wherein the film is formed using a process chosen from a physical vapor deposition (PVD) process, an evaporation deposition process, an electron beam vapor deposition process, a sputter deposition process, an arc vapor deposition process, and an ion plating process.

18. The film of claim 1, wherein the film is formed using a chemical vapor deposition (CVD) process, an atmospheric pressure CVD (APCVD) process, a low-pressure CVD (LPCVD) process, an aerosol assisted CVD (AACVD) process, a plasma enhanced CVD (PECVD) process, an atomic layer CVD (ALCVD or ALD) process, a metalorganic CVD (MOCVD) process, and an initiated CVD (iCVD) process.

19. The film of claim 1, wherein the substrate is a semiconductor processing apparatus component.

20. (canceled)

21. The film of claim 1, wherein the film is formed by a process that comprises heating the substrate to a temperature of about 21° C. to about 500° C. when the film is deposited.

22. The film of claim 1, wherein the film has been exposed to a fluorine gas plasma.

23. A plasma etch-resistant article comprising a substrate and a film, wherein the film comprises an yttria material and at least a portion of the yttria material is present in the film in a crystal phase having a crystal lattice structure and at least 50% of the yttria material is in a form of a monoclinic crystal system.

24. The article of claim 23, wherein the film has been exposed to a fluorine gas plasma.

25. A method of manufacturing an article comprising depositing an yttria material on a substrate to form a film, wherein the film comprises the yttria material and at least a portion of the yttria material present in the film is in a crystal phase having a crystal lattice structure, wherein at least 50% of the yttria material present in the film is in a form of a monoclinic crystal system.

26.-37. (canceled)

38. A method of increasing the plasma etch resistance of a substrate comprising depositing a yttria material on the substrate to form a film on the surface(s) of the substrate, wherein the film comprises the yttria material and at least a portion of the yttria material present in the film is in a crystal phase having a crystal lattice structure, wherein at least 50% of the yttria material present in the film is in a form of a monoclinic crystal system.

39.-50. (canceled)

51. The method of claim 38, further comprising exposing the film to a fluorine gas plasma.

52. The method of claim 51 wherein the film is exposed for at least about 4 hours.

53. The method of claim 51, wherein the exposure is effectuated using a process chosen from remote plasma exposure and reactive ion etch treatment.

54. A method of manufacturing a plasma resistant film having increased fracture toughness on a substrate comprising depositing a yttria material on the substrate to form a film on the surface(s) of the substrate, wherein the film comprises the yttria material and at least a portion of the yttria material present in the film is in a crystal phase having a crystal lattice structure, wherein at least 50% of the yttria material present in the film is in a form of a monoclinic crystal system, and exposing the film to a fluorine gas plasma.

55.-65. (canceled)
